(19) United States
(12) Patent Application Publication
(10) Pub. No.: US 2014/0084422 A1
(43) Pub. Date: Mar. 27, 2014

(54) Reclaimed Wafer And A Method For Reclaiming A Wafer

(71) Applicants: Tigran Dolukhanyan, Waltham, MA (US); George Glavin, Amherst, MA (US); Christopher D. Jones, Amherst, NH (US); Maureen A. Brosnan, West Boylston, MA (US); Theresa M. Besozzi, Milford, MA (US)

(72) Inventors: Tigran Dolukhanyan, Waltham, MA (US); George Glavin, Amherst, MA (US); Christopher D. Jones, Amherst, NH (US); Maureen A. Brosnan, West Boylston, MA (US); Theresa M. Besozzi, Milford, MA (US)

(21) Appl. No.: 14/025,582

(22) Filed: Sep. 12, 2013

Related U.S. Application Data
(60) Provisional application No. 61/700,728, filed on Sep. 13, 2012.

(51) Int. Cl. H01L 21/02

(52) U.S. Cl. CPC H01L 21/02032; H01L 21/02617
USPC 257/618; 438/692; 438/478; 438/4

(57) ABSTRACT

Embodiments of the present invention relate to a reclaimed wafer, a method for reclaiming a wafer, a method for reclaiming a batch of wafers, and a method for forming electronic structures. After being reclaimed, the reclaimed wafers are essentially free of a residue.

### CROSS-REFERENCE TO RELATED APPLICATION

This application claims, priority under 35 U.S.C. §119(e) to U.S. Patent Application No. 61/700,728 entitled “A Reclaimed Wafer And Method For Reclaiming A Wafer” by Dolukhanyan et al., filed Sep. 13, 2012, which is assigned to the current assignee hereof and incorporated herein by reference in its entirety.

### BACKGROUND

1. Field of the Disclosure

The following is directed to reclaimed wafers and methods for reclaiming a wafer, and particularly to returning a wafer into an essentially virgin state.

2. Description of the Related Art

In the semiconductor and optics industry, wafers or donor substrates are used in, for example, metal organic chemical vapour deposition (MOCVD) processes which deposit a material onto a wafer to form structures such as short wavelength LED's, LD's, and other electronic devices including high power, high frequency, high temperature transistors and integrated circuits. For example, short wavelength (e.g., blue/green to ultraviolet) LED's are fabricated using the Group III-nitride semiconducting material gallium nitride (GaN). In many applications, it is desirable to separate the wafer from the deposited layers. One known method to separate the wafer from the deposited layers is a laser lift off procedure. After lift off, residue from the deposited layers of material and any intermediate layers, such as bonding layers, buffer layers, growth promoting layers, etc. may remain on the surface of the wafer. Moreover, in other applications, defects may arise during production of the semiconductor or optical device using the wafer, leading to a wasted wafer. Due to the high cost of wafers produced from, for example, sapphire, diamond or the like, it is desirable to reclaim a wafer to use again in another deposition process, such as MOCVD. It is known to attempt to remove the deposited layers and/or the residue remaining after a lift off procedure and reclaim the wafer by methods such as grinding or chemical mechanical polishing (CMP). However, such CMP methods do not completely remove the residue and can damage the wafer. Grinding is difficult to control tightly, and will significantly change the dimensions of the wafer. Even more problems arise when the size of the wafer increases. Current lift-off techniques leave a larger amount of residue and larger pieces of residue as the size of the wafer increases. Moreover, the larger wafers are more susceptible to chipping and cracking during procedures such as CMP. Furthermore, the wafer and the deposited layers and/or residue have different material removal rates during procedures such as CMP, resulting in an uneven surface. Still further, some substrates may also have physical features, such as beveled edges, which make CMP techniques impractical. Still further, methods such as CMP are impractical when features such as beveled edges are present on the wafer.

Therefore a need exists to provide a reclaimed wafer and a method to reclaim a wafer where the wafer is returned to an essentially virgin state.

### SUMMARY

One embodiment is drawn to a reclaimed wafer configured to support more than one group of electronic structures, wherein the reclaimed wafer comprises sapphire, and wherein the reclaimed wafer is essentially free of a residue.

Another embodiment is drawn to a reclaimed wafer having a top surface, a side surface, and an angled surface between the top surface and the side surface, wherein the reclaimed wafer comprises sapphire, wherein the reclaimed wafer is essentially free of a residue on the top surface, and wherein the reclaimed wafer has a dimensional ratio of a width to a height of greater than about 76:1.

Another embodiment is drawn to a reclaimed wafer having a top surface, a side surface, and an angled surface between the top surface and the side surface, wherein the reclaimed wafer comprises sapphire, wherein the reclaimed wafer is essentially free of a residue on the top surface, and wherein the reclaimed wafer has a dimensional ratio of a width to a height of the reclaimed wafer of from 0.1 to 10% greater than a dimensional ratio of a virgin wafer.

Another embodiment is drawn to a reclaimed wafer having a top surface, a side surface, and an angled surface between the top surface and the side surface, wherein the reclaimed wafer comprises sapphire, wherein the reclaimed wafer is essentially free of a residue on the angled surface, and wherein the reclaimed wafer has a dimensional ratio of a width to a height of greater than about 76:1.

Another embodiment is drawn to a reclaimed wafer having a top surface, a side surface, and an angled surface between the top surface and the side surface, wherein the reclaimed wafer comprises sapphire, wherein the reclaimed wafer is essentially free of a residue on the angled surface, and wherein the reclaimed wafer has a dimensional ratio of a width to a height of the reclaimed wafer of from 0.1 to 10% greater than a dimensional ratio of a width to a height of a virgin wafer.

Yet another embodiment is drawn to a batch of at least 1, at least 10, at least 20, at least 30, at least 40, at least 50, at least 60, at least 70, at least 80, at least 90, or at least 100 reclaimed wafers, wherein the batch of reclaimed wafers has an average content of residue on a surface of the wafer which covers from about 0.00001% to about 0.01% of the surface area of the wafer.

Yet another embodiment is drawn to a method for forming an electronic structure comprising: providing a wafer comprising sapphire; depositing a layer, wherein the depositing comprises an epitaxial deposition; forming an electronic structure; separating the layer and electronic structure from the wafer, wherein a residue remains on the wafer after separating, and wherein the residue comprises a III-V nitride; immersing the wafer in a first etchant composition comprising KOH; polishing the wafer; and depositing another layer on the wafer, wherein the depositing comprises an epitaxial deposition.

Yet another embodiment is drawn to method for reclaiming a wafer comprising: providing a wafer comprising sapphire and a residue deposited on the sapphire, wherein the residue comprises a III-V nitride; immersing the wafer in a first etchant composition comprising KOH; and polishing the wafer.

### BRIEF DESCRIPTION OF THE DRAWINGS

The present disclosure may be better understood, and its numerous features and advantages made apparent to those skilled in the art by referencing the accompanying drawings.

FIG. 1 illustrates a virgin wafer according to an embodiment of the present invention.

FIG. 2 illustrates a rectangular wafer according to an embodiment of the present invention.

FIG. 3 illustrates a wafer having a layer disposed thereon according to an embodiment of the present invention.

FIG. 4 illustrates a wafer having two layers disposed thereon according to an embodiment of the present invention.

FIG. 5 illustrates a wafer having residue disposed thereon according to an embodiment of the present invention.

FIG. 6 illustrates a wafer having residue disposed thereon according to an embodiment of the present invention.

FIG. 7 illustrates a reclaimed wafer according to an embodiment of the present invention.

FIG. 8 illustrates a process flow diagram according to a method for forming an electronic structure according to an embodiment of the present invention.

FIG. 9A illustrates a process flow diagram according to a method for reclaiming a wafer according to an embodiment of the present invention.

FIG. 9B illustrates a process flow diagram according to a method for reclaiming a wafer according to an embodiment of the present invention.

FIG. 10 illustrates optical images of wafers comprising residue of LED, Au, and GaN according to an embodiment of the present invention.

FIG. 11 illustrates an SEM image of a wafer edge after immersion in aqua regia with GaN residue remaining on the wafer according to an embodiment of the present invention.

FIG. 12 illustrates an optical image of a wafer edge after immersion in aqua regia with GaN residue remaining on the wafer according to an embodiment of the present invention.

FIG. 13 illustrates an optical image of a wafer edge after immersion in KOH showing partial removal of GaN residue according to an embodiment of the present invention.

FIG. 14 illustrates a SEM image of a wafer edge after immersion in KOH showing partial removal of GaN residue according to an embodiment of the present invention.

FIG. 15 illustrates a SEM image of a wafer edge after immersion in KOH showing partial removal of GaN residue according to an embodiment of the present invention.

FIG. 16 illustrates a SEM image of a wafer edge after immersion in KOH showing essentially complete removal of GaN residue according to an embodiment of the present invention.

FIG. 17 illustrates a SEM image of a wafer edge after immersion in KOH showing essentially complete removal of GaN residue according to an embodiment of the present invention.

FIG. 18A illustrates an AFM image of a wafer top surface showing that essentially no etching of the wafer has occurred according to an embodiment of the present invention.

FIG. 18B illustrates an AFM image of a wafer edge surface showing that essentially no etching of the wafer has occurred according to an embodiment of the present invention.

### DETAILED DESCRIPTION

As used herein, the phrase “reclaimed wafer” can refer to a substrate configured to support more than one group of electronic structures at different times on the surface than otherwise could be supported at a single time on a surface of a virgin wafer.

As used herein, “group of electronic structures” can refer to the maximum number of the electronic structures that may be disposed on a growth surface of a wafer at a given time.

As used herein, the phrase “virgin wafer” can refer to a wafer configured to support a group of electronic structures at a single time. For example, a virgin wafer may include a wafer that does not nor has not had a group of electronic structures disposed thereon.

As used herein, the term “residue” may refer to material(s) that remain on a wafer after one or more layers which have been deposited on the wafer are at least partially removed.

As used herein, the phrase “essentially free of a residue” can refer to a surface of a wafer having from about 0.00001% to about 0.01% of the surface area containing residue.

The following is generally directed to a method of reclaiming a wafer and a reclaimed wafer, particularly wafers comprising sapphire.

FIG. 1 illustrates a virgin wafer 100 having a top surface 110, a side surface 120, an angled surface 130 between the top surface 110 and the side surface 120, and a bottom surface. 140. The virgin wafer 100 may be formed by, for example, by the methods disclosed in US 2008/0164458, which is incorporated herein by reference.

The virgin wafer 100 may be formed from materials including, but not limited to, insulating, semiconducting, and a combination thereof. In certain embodiments, the virgin wafer 100 may be formed from materials comprising oxides, carbides, nitrides, borides, and combinations thereof. In still further embodiments, the virgin wafer 100 may be formed from materials comprising sapphire, diamond, silicon, quartz, zinc oxide, magnesium oxide, lithium aluminum oxide, a group-III-V metal nitride material that is different than the residue material, or combinations thereof. In yet further embodiments, the virgin wafer 100 may comprise sapphire or may consist essentially of sapphire.

In certain embodiments, the virgin wafer 100 may have a crystal orientation such that the c-axis of the crystal is disposed close to perpendicular to the top surface 110 of the wafer. However, in the case of a sapphire material, it will be appreciated that other orientations are suitable, including for example, an r-face orientation, an a-face orientation. Moreover, the virgin wafer 100 may have a select off-cut, measured as an angle between the perpendicular c-axis relative to an axis extending perpendicular to the top surface 110 of the virgin wafer 100.

In certain embodiments, the virgin wafer 100 may have a surface roughness (Ra) on the top surface 110 of less than about 5 nm, less than about 3 nm, less than about 2 nm, less than about 1 nm, less than about 0.6 nm, or less than about 0.4 nm.

In certain embodiments, the virgin wafer 100 may have a surface roughness (Ra) on the angled surface 130 of less than about 20 μm, less than about 15 μm, less than about 10 μm, less than about 8 μm, less than about 5 μm, less than about 3 μm, or less than about 2 μm.

In certain embodiments, the virgin wafer 100 may have a surface roughness (Ra) on the bottom surface 140 of from about 0.01 nm to about 2000 nm, about 0.1 nm to about 1500 nm, or about 0.3 nm to about 1200 nm.

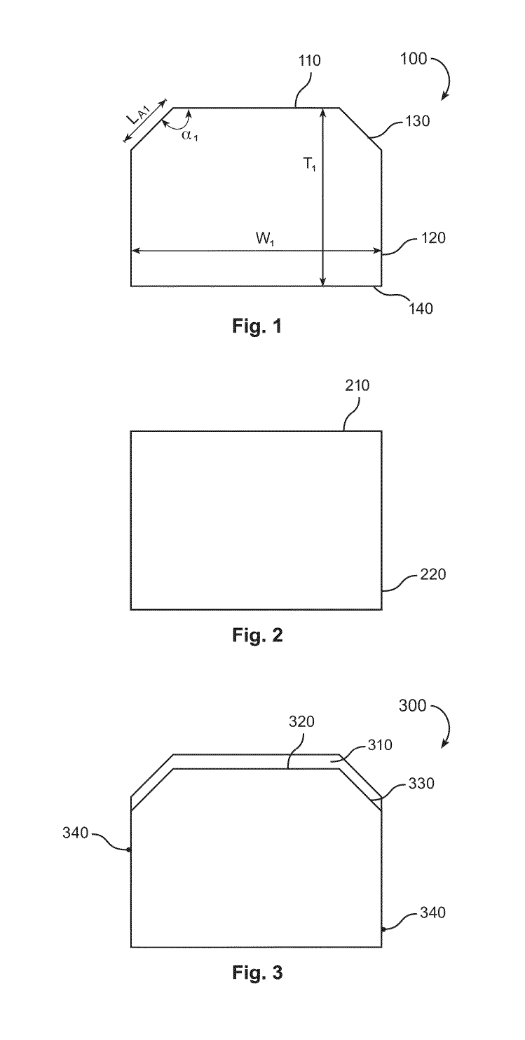

Referring again to FIG. 1, the angled surface 130 can form an angle α₁ of about 135° with the top surface 110. In certain other embodiments, the angled surface 130 can form an angle α₁ of less than 180° or from 91° to 179°, from 110° to 160°, 120° to 150°, or 130° to 140° with the top surface 110. In certain other embodiments, as particularly illustrated in FIG. 2, the top surface 210 may be adjacent to and substantially perpendicular to the side surface 220. In other words, in certain embodiments, there may be no angled surface.

The virgin wafer 100 can have a diameter D₁ of the top surface 110. In certain embodiments, D₁ can be no less than about 4 inches, such as not less than about 4.5 inches, no less than about 5 inches, no less than about 5.5 inches, or no less than about 6 inches. In other, non-limiting embodiments, D₁ can be no greater than about 15 inches, such as no greater than about 14 inches, no greater than about 13 inches, no greater than about 12 inches, no greater than about 11 inches, or no greater than about 10 inches. It will be appreciated that the diameter can be within a range between any of the minimum and maximum values noted above.

The top surface 110 of the virgin wafer 100 can have a surface area SA₁. In certain embodiments, SA₁ can be no less than about 12.56 square inches, such as no less than about 15.9 square inches, no less than about 19.63 square inches, or no less than about 28.26 square inches. In other, non-limiting embodiments, SA₁ can be no greater than about 176.625 square inches, such as no greater than about 153.86 square inches, no greater than about 132.665 square inches, no greater than about 113.04 square inches, no greater than about 94.985 square inches, or no greater than about 78.5 square inches. It will be appreciated that the surface area can be within a range between any of the minimum and maximum values noted above.

The virgin wafer 100 can have a width W₁ and a thickness T₁. In certain embodiments, the width W₁ can be greater than about 10 mm, greater than about 50 mm, greater than about 100 mm, greater than about 150 mm, greater than about 200 mm, greater than about 250 mm, greater than about 300 mm, or greater than about 400 mm. In certain embodiments, the width W₁ can be from about 10 mm to about 1000 mm, about 50 mm to about 800 mm, or about 100 mm to about 600 mm. In certain embodiments, the virgin wafer 100 can have a thickness T₁ of greater than about 0.01 mm, greater than about 0.05 mm, greater than about 0.1 mm, greater than about 0.3 mm, greater than about 0.5 mm, or greater than about 0.7 mm. In certain embodiments, the virgin wafer 100 can have a thickness T₁ of from about 0.01 mm to about 10 mm, about 0.1 mm to about 2 mm, or about 0.5 mm to about 1.3 mm. It is to be understood that the width W₁ refers to the longest longitudinal dimension as viewed from the top. The width W₁ may be equivalent to the diameter of the wafer. In certain embodiments, the virgin wafer 100 can have a dimensional ratio DR₁ of the width W₁ to the thickness T₁ as calculated by formula 1 below:

$$\frac{Width of Wafer Growth Substrate ( W )}{Thickness of Wafer Growth Substrate ( T )} = Dimensional Ratio ( DR ) \qquad ( 1 )$$

For example, a wafer which is 150 mm in width and 1 mm in thickness would have a dimensional ratio of 150. In certain embodiments, the virgin wafer 100 can have a dimensional ratio greater than about 75:1, greater than about 85:1, greater than about 100:1, greater than about 120:1, greater than about 150:1, greater than about 170:1, greater than about 190:1, greater than about 210:1, greater than about 250:1, greater than about 300:1, or greater than about 350:1.

In certain embodiments, the virgin wafer 100 can have a length of the angled surface L_{A1}. The length of the angled surface L_{A1} may be from 5 to 1000 μm, 10 to 800 μm, 50 to 500 μm, or 100 to 300 μm.

FIG. 3 illustrates a wafer 300 having a first layer 310 disposed on the top surface 320 and the angled surface 330 of the wafer 300. Material(s) 340 which form the layer may also be disposed on any exposed surface of the wafer 300. For example, in certain processes to deposit a layer on the wafer, such as a MOCVD processes, inherently the material(s) being deposited to form the layer may also be deposited on non-targeted surfaces of the wafer, such as the side and/or bottom surfaces.

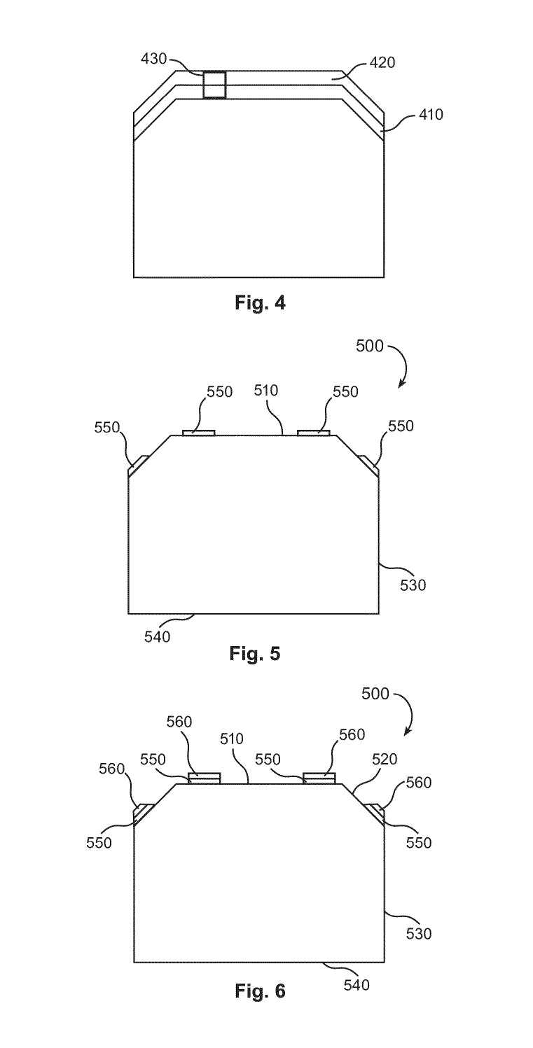

In certain embodiments, as particularly illustrated in FIG. 4, a second layer 420 may be deposited on the first layer 410. It is to be understood that any number of layers may be deposited on the wafer. For example, the layers may be deposited, patterned, and/or manipulated so as to form an electronic structure 430, such as an LED.

Referring now to FIGS. 5 and 6 there is illustrated a wafer 500 after the layer(s) have been separated from the wafer 500. FIG. 5 illustrates an embodiment having a first layer of residue 550, and FIG. 6 illustrates an embodiment having a first layer of residue 550 and a second layer of residue 560. Residue 550 and 560 from the layer(s) is disposed on the top surface 510 and the angled surface 520. However, it is to be understood that residue from the layer(s) or the material(s) forming the layer(s) may remain on the top surface 510, angled surface 520, side surface 530, bottom surface 540, or a combination thereof.

The residue may contain any material which is different than the material of the wafer. In certain embodiments, the residue may comprise a semiconductor material, an insulator material, conductor material, a barrier layer, a growth promoting layer, or combinations thereof. For example, the residue may comprise a semiconducting material, such as, for example, a Group III-V nitride, such as gallium nitride (GaN), (InGaN), (AlGaN). The residue may comprise a conductor material which may comprise a metallic material, such as, for example Au. In certain embodiments, the residue may contain any material that is used in the formation of the electronic structure, and/or at least part of, a whole, or a plurality of formed electronic structures. In particular embodiments, the residue may comprise or consists essentially of GaN and Au. Au may be disposed atop of the GaN, such as is depicted in FIG. 6. In certain other embodiments, the residue may consist essentially of GaN.

In certain embodiments, the percentage of surface area of the wafer 500 having a residue disposed thereon may be greater in the angled surface than the top surface. For example, the percentage of surface areas having residue disposed on the angled surface may be 100% or less, 95% or less, 90% or less, 85% or less, 80% or less, 75% or less, 70% or less, 65% or less, 60% or less, 55% or less, 50% or less, 45% or less, 40% or less, 35% or less, 30% or less, 25% or less, 20% or less, 10% or less, 5% or less, or 1% or less. The percentage of surface area of the top surface of the wafer having residue disposed thereon may be 100% or less, 95% or less, 90% or less, 85% or less, 80% or less, 75% or less, 70% or less, 65% or less, 60% or less, 55% or less, 50% or less, 45% or less, 40% or less, 35% or less, 30% or less 20% or less, 15% or less, 10% or less, 5% or less, 2 or less, or 1% or less.

It is to be understood that the pattern or residue location, size, and composition can vary based on a multitude of factors including, but not limited to, layer separation procedures, layer deposition procedures, layer compositions, etc.

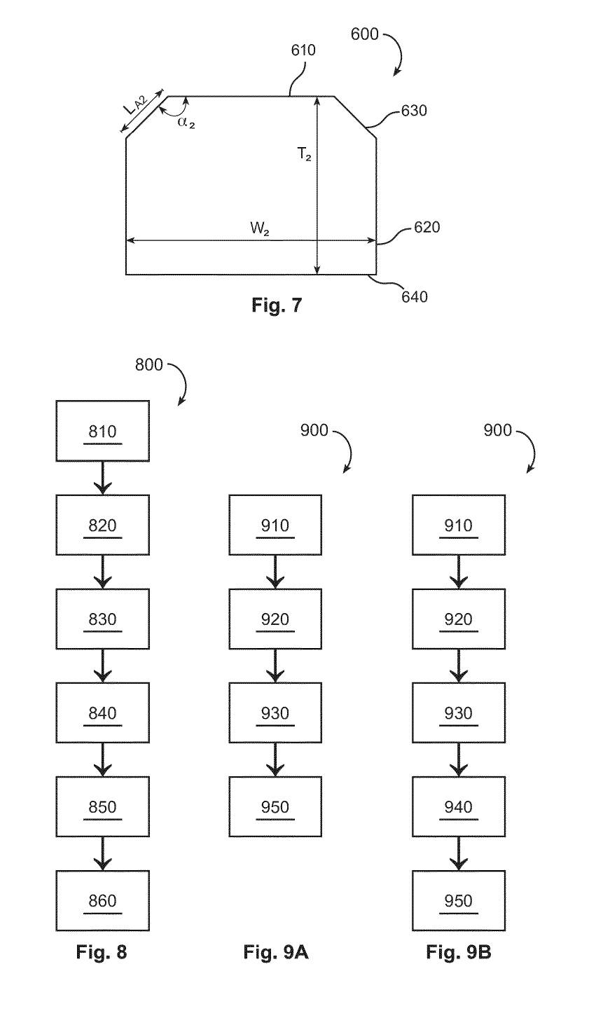

FIG. 7 illustrates a reclaimed wafer 600 that has been reclaimed in accordance with an embodiment as described herein. The reclaimed wafer 600 has a top surface 610, a side surface 620, an angled surface 630 between the top surface 610 and the side surface 620, and a bottom surface 640. The angled surface 630 forms an angle α₂ with the top surface. The reclaimed wafer 600 is essentially free of residue on the top surface 610, angled surface 630, side surface 620, and bottom surface 640. However, in certain embodiments, the reclaimed wafer 600 may be essentially free of the residue on any one or combinations of the top surface 610, angled surface 630, side surface 620, and bottom surface 640.

The top surface 610 of the reclaimed wafer 600 can have a diameter D₂. In certain embodiments, D₂ may be substantially the same or slightly greater than D₁ of the virgin wafer. For example, D₂ may be about 0.1% greater, about 0.2% greater, about 0.5% greater, about 0.8% greater, or about 1% greater than D₁. In other embodiments, D₂ may be no more than about 20% greater, such as no more than about 15% greater, no more than about 12% greater, no more than about 10% greater than, or no more than about 5% greater than D₁. In certain embodiments, D₂ may be at least about 4.004 inches, such as at least about 4.505 inches, at least about 5.005 inches, at least about 5.505 inches, or at least about 6.006 inches. In other, non-limiting embodiments, D₂ may be no greater than about 18 inches, such as no greater than about 16.8 inches, no greater than about 15.6 inches, no greater than about 14.4 inches, no greater than about 13.2 inches, or no greater than about 12 inches. It will be appreciated that the diameter D₂ can be within a range between any of the minimum and maximum values noted above.

The reclaimed wafer 600 can have a surface area SA₂ of the top surface 610. In certain embodiments, SA₂ may be substantially the same or slightly greater than SA₁ of the virgin wafer. For example, SA₂ may be about 0.0001% greater than SA₁, about 0.0004% greater, about 0.0025% greater, about 0.0064% greater, or about 0.01% greater than SA₁. In other embodiments, SA₂ may be no more than about 4% greater than SA₁, such as no more than about 2.25% greater, no more than about 1.44% greater, no more than about 1% greater, or no more than about 0.25% greater than SA₁. In certain embodiments, SA₂ may be at least about 12.560013 square inches, such as at least about 15.90016 square inches, at least about 19.63002 square inches, or at least about 28.26003 square inches. In other, non-limiting embodiments, SA₂ may be no greater than about 247.275 square inches, such as no greater than about 215.404 square inches, no greater than about 185.731 square inches, no greater than about 158.256 square inches, no greater than about 132.979 square inches, or no greater than about 109.9 square inches. It will be appreciated that the surface area SA₂ can be within a range between any of the minimum and maximum values noted above.

Referring again to FIG. 7, in certain embodiments, the reclaimed wafer 600 may have an angle α₂ of the top surface 610 to the angled surface 630 which may be substantially the same as angle α₁ of the virgin wafer. As used herein when referencing the angle, the phrase “substantially the same” includes an angle α₂ within 101% of the angle α₁ of a virgin wafer. It is to be understood that angle α₂ may be the same, or greater, or smaller after each reclamation procedure.

The reclaimed wafer 600 can have a width W₂ and a thickness T₂. In certain embodiments, the width W₂ of the reclaimed wafer 600 may be substantially the same as the width W₁ of the virgin wafer. As used herein when referencing the width, the phrase “substantially the same” includes a width W₂ within 99.9% of the width W₁ of a virgin wafer. It is to be understood that the width W₂ refers the longest longitudinal dimension as viewed from the top. The width W₂ may be equivalent to the diameter of the wafer.

In certain embodiments, the reclaimed wafer 600 can have a thickness T₂ that may be substantially the same or slightly less than the thickness T₁ of the virgin wafer. For example, the thickness T₂ of the reclaimed wafer 600 may be from 0.00001% to 30% less, 0.001% to 25% less, 0.01% to 20% less, 0.1% to 18% less, 0.5% to 15% less, 1% to 10%, or 3% to 8% less than the thickness T₁ of the virgin wafer.

In certain embodiments, the reclaimed wafer 600 can have a dimensional ratio DR₂ of the width W₂ to the thickness T₂ (DR₂=W₂/T₂) that may be substantially the same or slightly greater than the dimensional ratio DR₁ of the width W₁ to the thickness T₁ of the virgin wafer (DR₁=W₁/T₁). For example, the dimensional ratio DR₂ may be from 0 to 40% greater, 0.00001 to 30% greater, 0.0001 to 25% greater, 0.1 to 20%, greater, 0.5 to 10% greater or 0.5 to 5% greater than the dimensional ratio DR₁ of the virgin wafer. For example, in certain embodiments, the reclaimed wafer 600 can have a dimensional ratio DR₂ of greater than about 76:1, greater than about 86:1, greater than about 101:1, greater than about 121:1, greater than about 151:1, greater than about 171:1, greater than about 191:1, greater than about 211:1, greater than about 251:1, greater than about 301:1, or greater than about 351:1.

In certain embodiments, the reclaimed wafer 600 can have a length of the angled surface L_{A2}. The length of the angled surface L_{A2} may be less than the length of the angled surface L_{A1} of the virgin wafer. For example, the length of the angled surface L_{A2} may be from 70 to 99.99%, 80 to 99.9%, 85 to 99%, 88 to 98%, or 90 to 97% of the length of the angled surface L_{A1} of the virgin wafer.

According to another aspect, a method for forming an electronic structure is provided. Referring to FIG. 8, according to certain embodiments, at block 810, the method may include providing a wafer, for example, providing the virgin wafer as illustrated in FIG. 1.

At block 820, a layer may then be deposited on at least the top surface of the wafer, for example, as illustrated in FIG. 3. The layer may also be deposited on the angled surface of the wafer. It is also to be understood that some of the material being deposited to form the layer may also be disposed on any exposed surface of the wafer.

In certain embodiments, the depositing may include a MOCVD process. Other suitable depositing process include, but are not limited to chemical vapor deposition (CVD), physical vapor transport (PVT), halide vapor phase epitaxy (HYPE), and molecular beam epitaxy (MBE).

At block 830, additional layers may also be deposited on the virgin wafer to thereby form, for example, an electronic structure. The layer(s) being deposited may be patterned, etched, or otherwise manipulated to from the electronic structure. It is to be understood that any number of layers, patterns, electrodes, or any other material or structure may be deposited on the wafer. In particular embodiments, the electronic structure comprises a light emitting diode (LED).

At block 840, the one or more layers may be separated from the wafer. For example, the separating may include a laser lift off procedure, such as described, for example, in U.S. Pat. No. 6,974,758, which is incorporated herein by reference. Other separation techniques may additionally or alternatively be used, such as, for example mechanical, physical, or chemical separation methods.

After the separation procedure, residue as described above, from at least the layer nearest the surface of wafer may remain on the surface of the wafer, such as, for example, as illustrated in FIG. 5. Residue may also be present from the additional layers. For example, as illustrated in FIG. 6, the residue may include a first layer and a second layer overlaying the first layer. In particular embodiments, the second layer may overlay and abut the sides of the first layer.

The residue may be comprised of materials as described above. In certain embodiments, the residue may comprise a semiconductor material, a conductor material, and insulating material, a barrier layer, a growth promoting layer, or combinations thereof. In particular embodiments, the residue may comprise or consist essentially of a first layer of GaN and a second layer of Au. In certain embodiments, the residue may include doped semiconductor material, such as, for example, n-doped or p-doped GaN. The residue may be thicker and/or relatively (based on percentage of surface area occupied) greater along the angled surface than the top surface as described above.

At block 850, the wafer may then be reclaimed by any of the methods described herein.

At block 860, the reclaimed wafer may again have one more layers deposited on thereon as described above. It is to be understood that the steps of forming the electronic structure, separating the electronic structure from the wafer, reclaiming the wafer and repeating can be performed any number of times. For example, in certain embodiments, the steps of forming the electronic structure, separating the electronic and reclaiming the wafer may be repeated more than 2, more than 3, more than 5, more than 6, more than 7 times using the same wafer. Put another way, in certain embodiments, the same wafer may be used to form 2 or more, 3 or more, 5 or more, 10 or more, 20 or more, or 30 or more groups of electronic structures. Moreover, it is to be understood that the particular deposition process used or the particular one or more layers deposited on the wafer may be different after each reclaiming step or groups of reclaiming steps.

According to another aspect, a method for reclaiming a wafer is provided. Referring to FIG. 9, according to one embodiment, at block 910, the method may include providing a wafer, for example, as illustrated in FIG. 5 comprising a residue disposed on the wafer.

In certain embodiments, at block 920, the method may first include polishing the wafer. Initial polishing may be performed, for example, in order to reduce the height of large particles of the residue material. Polishing methods may include, but are not limited to CMP polishing.

At block 930, the wafer may then be immersed in a first etching composition. The first etching composition may contain, for example, any material which may be effective at removing at least part of the residue. In certain embodiments, the first etching composition may comprise a basic material having a pH of at least about 8, 9, 10, or 11. For example, the first etching composition may include, but is not limited to hydroxides, such as, for example, potassium hydroxide (KOH). In certain embodiments, the first etching composition has an active component comprising or consisting essentially of KOH. In certain embodiments, the first etching composition may comprises a 10 to 90%, 15 to 80%, 20 to 70%, 25 to 60%, or 30 to 50% concentrated KOH solution in water.

The first etchant composition may be heated to a temperature of greater than 40° C., 50° C., 60° C., 70° C., 80° C. or 85° C. during the immersion of the wafer. In certain embodiments, the first etching composition may be heated to a temperature of from 40 to 140° C., 60 to 120° C., 70 to 110° C., or 80 to 100° C. during the immersion of the wafer.

The wafer may be immersed in the first composition for a period of time of, for example, greater than 8 hours, greater than 10 hours, greater than 15 hours, or greater than 20 hours. In certain embodiments, the wafer may be immersed in the first composition for a period of time of from 10 to 40 hours, 15 to 30 hours, or 20 to 30 hours.

After immersion in the first etching composition, the wafer may be rinsed and dried.

In certain embodiments, as particularly illustrated in FIG. 9B, at block 940, the wafer may be immersed in a second etching composition. In particular embodiments, the wafer may be immersed in the second etching composition before immersing in the first etching composition.

The second etching composition may comprise any material capable of etching the residue, and may be selected based on the residue materials. For example, in certain embodiments, the second etching composition may comprise an acid having a pH less than 6, 5, 4, 3, or 2. In particular embodiments, the second etching composition may comprise hydrochloric acid, HNO₃, or combinations thereof. In other embodiments, the second etching composition may be configured to etch a residue material disposed on the outermost surface of the residue. For example, in certain embodiments, the outermost surface of at least part of the residue may contain a metallic material, such as, for example, Au. It is to be understood that any number of different etching compositions and immersion steps may used in accordance with embodiments described herein.

In certain embodiments, each etching composition may be selected in response to the residue contents. For example, in certain embodiments, the second etching composition may be configured to etch a material disposed on the outer surface of a residue, such as Au. As another example, if the residue contains three different materials, three different etchant compositions may be used to remove a respective residue component. The sequence of use of each etchant composition and immersion step may be selected in relation to the order of residue components. For example, in an embodiment where the residue contains GaN disposed on the wafer and Au disposed on the GaN, the wafer may be immersed in the second etchant composition which is configured to etch the Au first, and subsequently immersed in the first etchant composition which is configured to etch the GaN.

The second etchant composition may be heated to a temperature of greater than 40° C., greater than 50° C., greater than 60° C., greater than 70° C., greater than 80° C., or greater than 85° C. during the immersion of the wafer. In certain embodiments, the second etching composition may be heated to a temperature of from 40 to 140° C., 60 to 120° C., 70 to 110° C., or 80 to 100° C. during the immersion of the wafer.

The wafer may be immersed in the second composition for a period of time of, for example, greater than 1 hour, greater than 2 hours, greater than 2.5 hours, or greater than 3 hours. In certain embodiments, the wafer may be immersed in the first composition for a period of time of from 1 to 10 hours, 1 to 8 hours, or 1 to 5 hours.

In certain embodiments, a batch of wafers may be immersed together in a bath of the particular etchant. For example, the batch may contain at least 10, at least 20, at least 30, at least 40, at least 50, at least 60, at least 70, at least 80, at least 90, or at least 100 wafers. Immersing a batch of wafers may occur in any immersion step described herein. For example, a batch of wafers may be immersed in the first etching composition and the batch of wafers may be immersed in the second etching composition, or any further immersion step.

In certain embodiments, during immersion of the wafer in either the first or second or any subsequent etchant composition, the method may further include imparting ultrasonic energy to the wafer or batch of wafers.

At block 950, the wafer may be chemically cleaned, such as by rinsing with a third composition, such as, for example, deionized water. The reclaimed wafer, dried, and the top surface may be polished to a surface roughness suitable for epitaxial deposition. For example, the top surface may be polished to an average surface roughness of from 0.1 to 0.4 nm, or as described above.

Following the reclamation method disclosed herein, the reclaimed wafer may be essentially free of a residue. In certain embodiments, an amount of residue covering of from 0.00001% to about 0.01% of the angled surface of the reclaimed wafer may remain. In certain embodiments, a batch of reclaimed wafers may be provided, in which there are at least 10, at least 20, at least 30, at least 40, at least 50, at least 60, at least 70, at least 80, at least 90, or at least 100 reclaimed wafers. The batch of wafers may have an average residue content of from 0.00001% to 0.01% on each angled surface of a wafer.

Moreover, after the reclamation method, the reclaimed wafer may have substantially the same dimensional ratio or slightly greater dimensional ratio as the virgin wafer, i.e. before the reclamation method, as more fully described above.

Embodiments may be in accordance with any one or more of the items as listed below.

Item 1. A reclaimed wafer configured to support more than one group of electronic structures, wherein the reclaimed wafer comprises sapphire, and wherein the reclaimed wafer is essentially free of a residue.

Item 2. A batch of at least 10, 20 30, 40, 50, 60, 70, 80, 90, or 100 reclaimed wafers, wherein the batch of reclaimed wafers has an average content of residue on a surface of the wafer which covers from about 0.00001% to about 0.01% of the surface area of the surface of the wafer

Item 3. A reclaimed wafer having a top surface, a side surface, and an angled surface between the top surface and the side surface, wherein the reclaimed wafer comprises sapphire, wherein the reclaimed wafer is essentially free of a residue on the top surface, and wherein the reclaimed wafer has a dimensional ratio of a width to a height of greater than about 76:1.

Item 4. A reclaimed wafer having a top surface, a side surface, and an angled surface between the top surface and the side surface, wherein the reclaimed wafer comprises sapphire, wherein the reclaimed wafer is essentially free of a residue on the top surface, and wherein the reclaimed wafer has a dimensional ratio of a width to a height of the reclaimed wafer of from 0.1 to 10% greater than a dimensional ratio of a virgin wafer.

Item 5. A reclaimed wafer having a top surface, a side surface, and an angled surface between the top surface and the side surface, wherein the reclaimed wafer comprises sapphire, wherein the reclaimed wafer is essentially free of a residue on the angled surface, and wherein the reclaimed wafer has a dimensional ratio of a width to a height of greater than about 76:1.

Item 6. A reclaimed wafer having a top surface, a side surface, and an angled surface between the top surface and the side surface, wherein the reclaimed wafer comprises sapphire, wherein the reclaimed wafer is essentially free of a residue on the angled surface, and wherein the reclaimed wafer has a dimensional ratio of a width to a height of the reclaimed wafer of from 0.1 to 10% greater than a dimensional ratio of a width to a height of a virgin wafer.

Item 7. The reclaimed wafer of any one of items 3-4, wherein the angled surface forms an angle of less than 180° with a top surface.

Item 8. The reclaimed wafer of any one of items 3-7, wherein a dimensional ratio of a width to a height of the reclaimed wafer is greater than about 101:1, greater than about 121:1, greater than about 151:1, greater than about 171:1, greater than about 191:1, greater than about 211:1, greater than about 251:1, greater than about 301:1, or greater than about 351:1.

Item 9. A method for forming an electronic structure comprising:
providing a wafer comprising sapphire;
depositing a layer, wherein the depositing comprises an epitaxial deposition;
forming an electronic structure;
separating the layer and electronic structure from the wafer, wherein a residue remains on the wafer after separating, and wherein the residue comprises a III-V nitride;
immersing the wafer in a first etchant composition comprising KOH;
polishing the wafer; and
depositing another layer on the wafer, wherein the depositing comprises an epitaxial deposition.

Item 10. The method of item 9, wherein the depositing a layer and/or depositing another layer on the wafer comprises a MOCVD process.

Item 11. The method of any one of items 9-10, wherein the process is repeated more than 2, more than 3, more than 5, more than 6, more than 7 times with the same wafer.

Item 12. The method of any one of items 9-11, wherein the electronic structure comprises a light emitting diode (LED).

Item 13. A method for reclaiming a wafer comprising:
providing a wafer comprising sapphire and a residue deposited on the sapphire, wherein the residue comprises a III-V nitride;
immersing the wafer in a first etchant composition comprising KOH; and
polishing the wafer.

Item 14. The method of any one of items 9-13, wherein the residue further comprises a metallic material.

Item 15. The method of item 14, further comprising immersing the wafer in a second etchant composition comprising an etchant configured to etch the metallic material.

Item 16. The method of item 15, wherein immersing in the second etchant composition is performed before immersing in the first etchant composition.

Item 17. The method of item 16, wherein the second etchant composition comprises concentrated hydrochloric acid, HNO₃, or combinations thereof.

Item 18. The method of any one of items 13-17 further comprising providing a wafer comprising a layer connected to the wafer; and
separating the layer from the wafer, wherein the residue remains on the wafer after separating.

Item 19. The method of item 18, wherein the separating includes laser lift-off.

Item 20. The method of any one of items 9-19, wherein the wafer has a top surface and an angled surface adjacent to the top surface, wherein the wafer comprises the residue on the angled surface.

Item 21. The method of any one of items 9-20, wherein the first composition comprises a 10 to 90%, 15 to 80%, 20 to 70%, 25 to 60%, or 30 to 50% KOH solution.

Item 22. The method of any one of items 9-21, wherein the first composition is heated to a temperature of greater than 40° C., 50° C., 60° C., 70° C., 80° C. or 85° C. during the immersion of the wafer.

Item 23. The method of any one of items 9-22, wherein the first composition is heated to a temperature of from 40 to 140° C., 60 to 120° C., 70 to 110° C., or 80 to 100° C. during the immersion of the wafer.

Item 24. The method of any one of items 9-23, wherein the wafer is immersed in the first composition for a period of greater than 8 hours, 10 hours, 15 hours, or 20 hours.

Item 25. The method of any one of items 9-24, wherein the wafer is immersed in the first composition for a period of 10 to 40 hours, 15 to 30 hours, or 20 to 30 hours.

Item 26. The method of any one of items 9-25 further comprising imparting ultrasonic energy to the wafer during immersion of the wafer in the first and/or second composition.

Item 27. The method of any one of items 9-26 further comprising chemically cleaning the wafer after immersing the wafer in the second composition.

Item 28. The method of any one of items 9-27 further comprising rinsing the wafer with a third composition and drying the wafer.

Item 29. The method of item 28, wherein the third composition comprises deionized water (DI).

Item 30. The method of any one of items 9-29 further comprising polishing the wafer after immersing the wafer in the first composition.

Item 31. The method of any one of items 9-30 further comprising polishing the wafer after before immersing the wafer in the first composition.

Item 32. The method of any one of items 9-31, wherein the polishing includes chemical mechanical polishing (CMP).

Item 33. The reclaimed wafer or method for reclaiming a wafer of any one of the preceding items, wherein the reclaimed wafer consists essentially of sapphire.

Item 34. The reclaimed wafer, the method for reclaiming a wafer, or the method for forming an electronic structure of any one of the preceding items, wherein the residue comprises a conductor material, a semiconductor material, an insulating material, a barrier layer, a growth promoting layer, or combinations thereof.

Item 35. The reclaimed wafer, the method for reclaiming a wafer, or the method for forming an electronic structure of any one of the preceding items, wherein the residue comprises a semiconductor material comprising a group III-V nitride.

Item 36. The reclaimed wafer, the method for reclaiming a wafer, or the method for forming an electronic structure of any one of the preceding items, wherein the residue comprises GaN.

Item 37. The reclaimed wafer, the method for reclaiming a wafer, or the method for forming an electronic structure of any one of the preceding items, wherein the residue comprises a metallic material.

Item 38. The reclaimed wafer, the method for reclaiming a wafer, or the method for forming an electronic structure of any one of the preceding items, wherein the residue comprises Au.

Item 39. The reclaimed wafer, the method for reclaiming a wafer, or the method for forming an electronic structure of any one of the preceding items, wherein the residue comprises a first layer and a second layer, wherein the first layer comprises a III-V nitride, wherein the second layer comprises a metallic material, and wherein the second material is at least partially disposed atop of the first material.

Item 40. The reclaimed wafer, the method for reclaiming a wafer, or the method for forming an electronic structure of any one of the preceding items, wherein the angled surface has a length of from 50 to 500 um, 75 to 475 um, 100 to 450 um, 125 to 425 um, 150 to 400 um, 175 to 375 um, 200 to 350 um, 225 to 325 um, or 250 to 300 um.

Item 41. The reclaimed wafer, the method for reclaiming a wafer, or the method for forming an electronic structure of any one of the preceding items, wherein the top surface of the wafer has an average surface roughness of less than 1 nm, less than 0.8 nm, less than 0.5 nm, less than 0.3 nm.

Item 42. The reclaimed wafer, the method for reclaiming a wafer, or the method for forming an electronic structure of any one of the preceding items, wherein the top surface of the wafer has an average surface roughness of from 0.01 to 1 nm, from 0.05 to 0.8 nm, from 0.07 to 0.5 nm, from 0.1 to 0.3 nm.

Item 43. The reclaimed wafer, the method for reclaiming a wafer, or the method for forming an electronic structure of any one of the preceding items, wherein top surface has a lower average surface roughness than the angled surface.

Item 44. The reclaimed wafer, the method for reclaiming a wafer, or the method for forming an electronic structure of any one of the preceding items, wherein a length of the angled surface of the reclaimed wafer is less than the length of the angled surface of a virgin wafer.

Item 45. The reclaimed wafer, the method for reclaiming a wafer, or the method for forming an electronic structure of any one of the preceding items, wherein a length of the angled surface of the reclaimed wafer is from 70 to 99.99%, 80 to 99.9%, 85 to 99%, 88 to 98%, or 90 to 97% of the length of the angled surface of a virgin wafer.

### EXAMPLES

### Example 1

### Reclamation of Sapphire Wafer Having GaN, Au and LED Residue

12 sapphire wafers plus a control wafer containing different amounts and types of residue were reclaimed. All of the wafers contain GaN on at least 50% of the surface area of the angled surface. Table 1 provided below and FIG. 10 illustrate the wafer characteristics and the residue contents and characteristics. Table 2 below illustrates the parameters of the control wafer X at different stages of the reclaim process.

TABLE 1

| | | | | Visual Characteristics | | |
|---|---|---|---|---|---|---|
| | | Wafer | | | GaN/Au on | |
| | Wafer Width | Height | Dimensional | LED on Top | angled | |
| Example | (mm) | (μm) | Ratio | Surface? | surface | Window? |
| A | 150.01 | 988 | 152 | No | Yes | Yes |
| B | 150.02 | 1011 | 148 | No | Yes | No |
| C | 150.03 | 979 | 153 | No | Yes | No |
| D | 150.01 | 987 | 152 | No | Yes | No |
| E | 150.02 | 991 | 151 | Yes | Yes | No |
| F | 150.02 | 988 | 152 | No | Yes | No |
| G | 150.04 | 995 | 151 | No | Yes | Yes |
| H | 150.02 | 988 | 152 | No | Yes | No |
| I | 150.02 | 983 | 153 | No | Yes | No |
| J | 150.03 | 995 | 151 | No | Yes | No |
| K | 150.02 | 990 | 152 | Yes | Yes | Yes |
| L | 150.01 | 995 | 151 | No | Yes | No |
| X | 150.02 | 989 | 152 | No | Yes | No |

TABLE 2

| | | | | | Surface | |
|---|---|---|---|---|---|---|
| | | | | Surface | Roughness after | Surface Roughness |
| | Wafer | Wafer | Wafer | Roughness after | aqua regia | after KOH treatment |
| | Width | Height | Height | polishing, nm (st. | treatment, nm (st. | (final), nm (st. |
| Example | (mm) | Incoming | Final | deviation, n = 3) | deviation, n = 3) | deviation, n = 3) |
| X | 150.02 | 989 μm | 972 μm | 0.23 (0.05) | 0.22 (0.02) | 0.23 (0.03) |

The top surface of each of the examples A-X was polished a first time for 2.15 hours. The top surface of each of the examples A-X was then polished a second for 30 minutes. Table 3. provided below illustrates the thickness of the wafer after polishing.

TABLE 3

| | Material removed | Thickness after | Reclaimed Wafer |
|---|---|---|---|
| | from top surface | Polishing | Dimensional |
| Example | (μm) | (μm) | Ratio |
| A | 28 | 958 | 157 |
| B | 28 | 979 | 153 |
| C | 11 | 967 | 155 |
| D | 26 | 958 | 157 |
| E | 13 | 978 | 153 |
| F | 10 | 976 | 154 |
| G | 11 | 981 | 153 |
| H | 10 | 977 | 154 |
| I | 11 | 972 | 154 |
| J | 12 | 981 | 153 |
| K | 12 | 978 | 154 |
| L | 10 | 984 | 152 |
| X | 17 | 972 | 154 |

Examples A-X were visually inspected and it was seen that residue was present on the angled surface, but was essentially free of residue on the top surface. Examples A-X were then immersed in concentrated aqua regia. The aqua regia was heated to 60° C. for 2 hours.

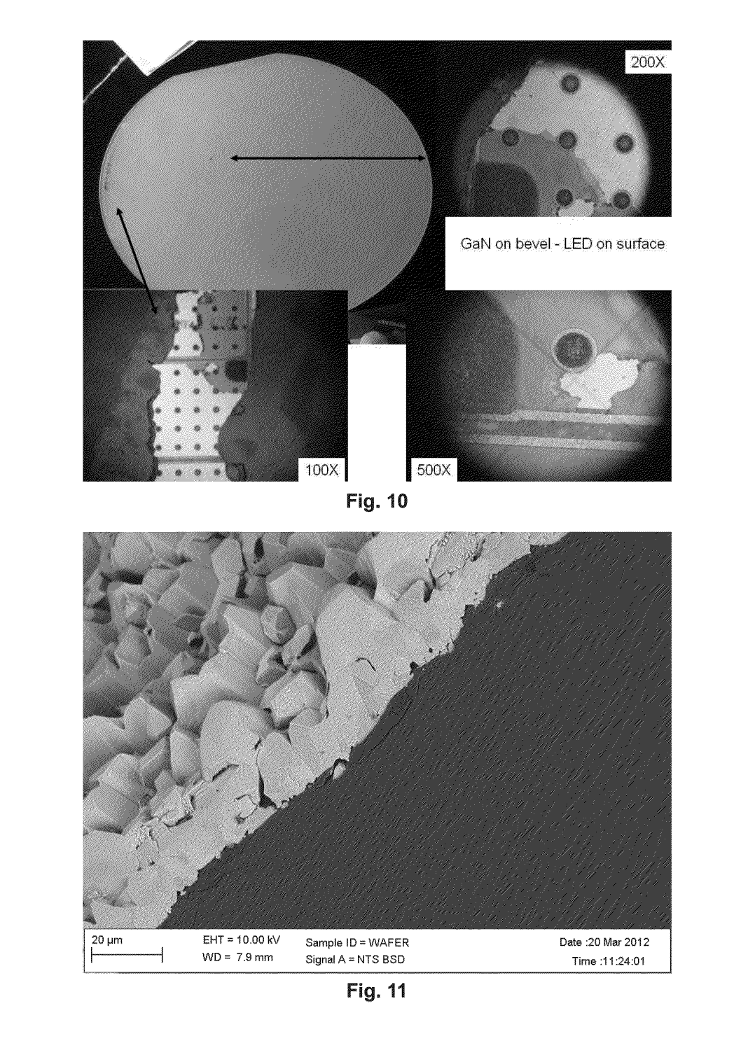

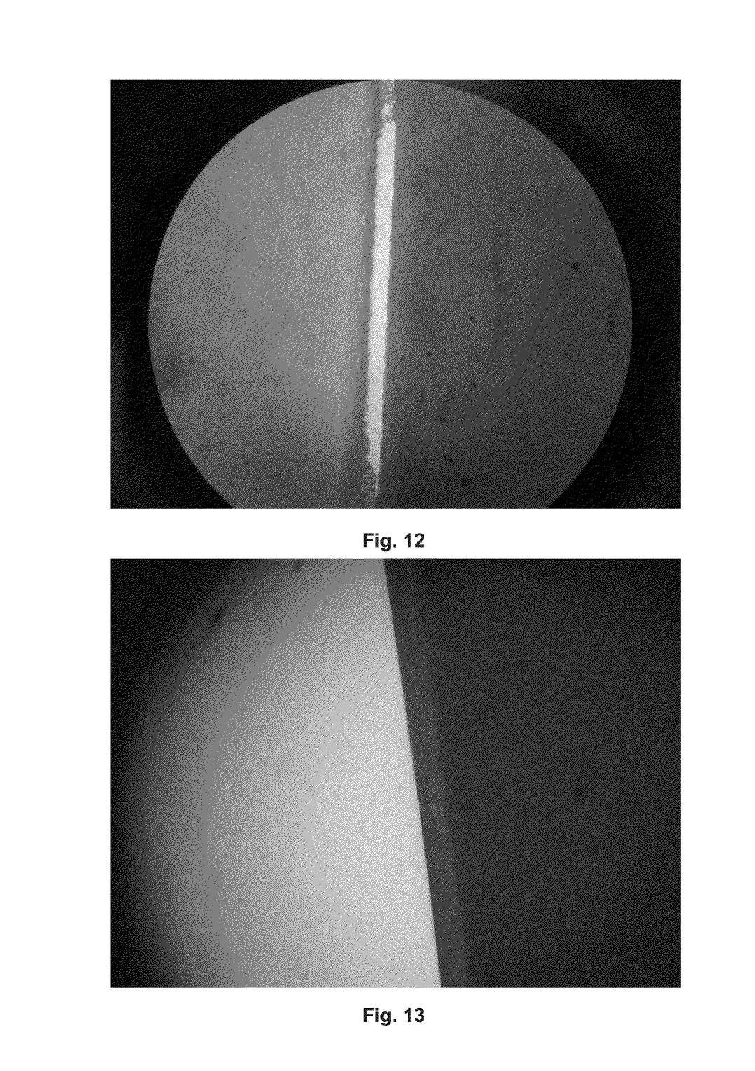

Examples A-X were then rinsed in deionized water and air dried. Examples A-X were then examined and found to be essentially free of visible Au residue and had GaN residue on the angled surface as illustrated in FIGS. 11 and 12.

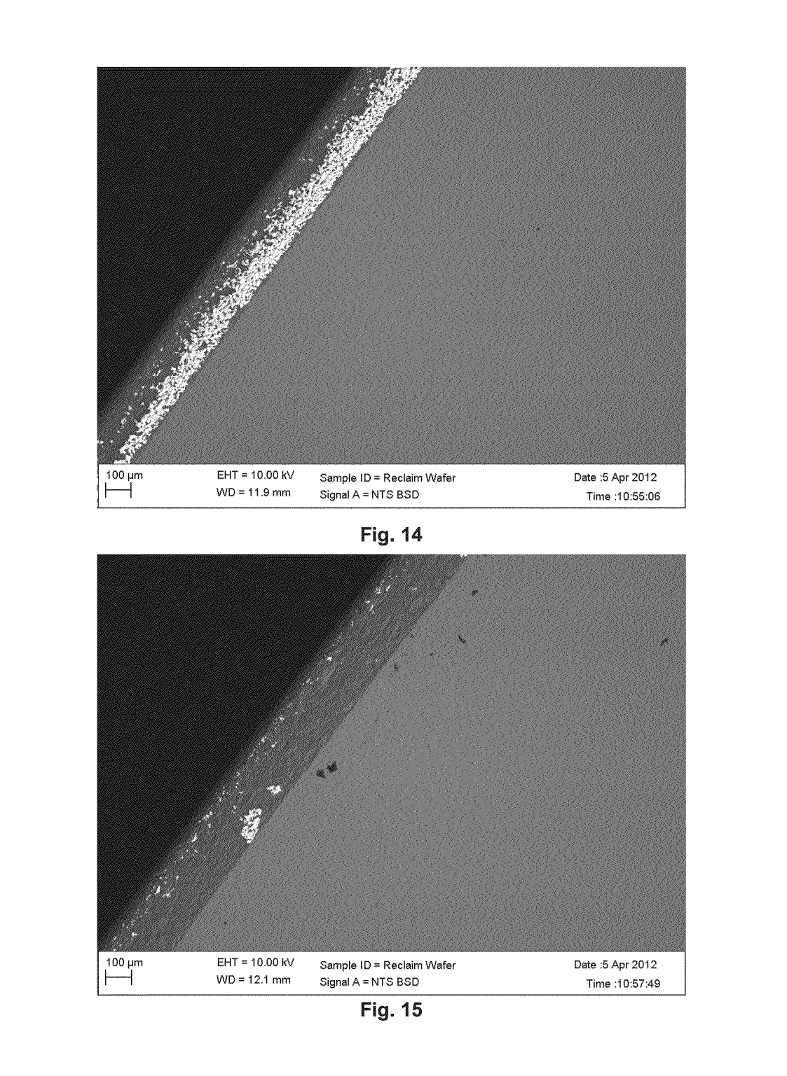

Examples A-X were then immersed in a KOH solution and heated to a temperature of 85° C. for 12 hours under intermittent ultrasonication for a total of 4 hours. Examples A-X were then inspected and it was found that partial removal of GaN was observed as illustrated in FIGS. 13, 14 and 15.

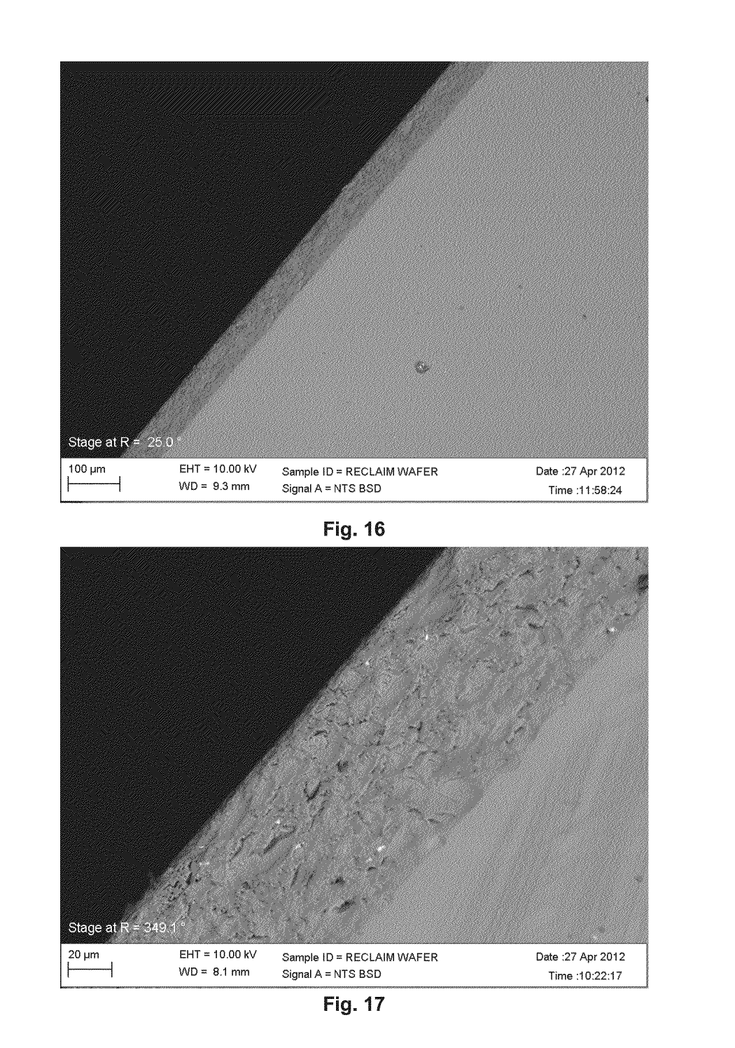

Examples A-X were then immersed in KOH again and heated to a temperature of 85° C. for 16 hours under intermittent ultrasonication for a total of 4 hours. Examples A-X were then inspected and it was found that the angled surface of the reclaimed wafer was essentially free of GaN residue as illustrated in FIGS. 16 and 17.

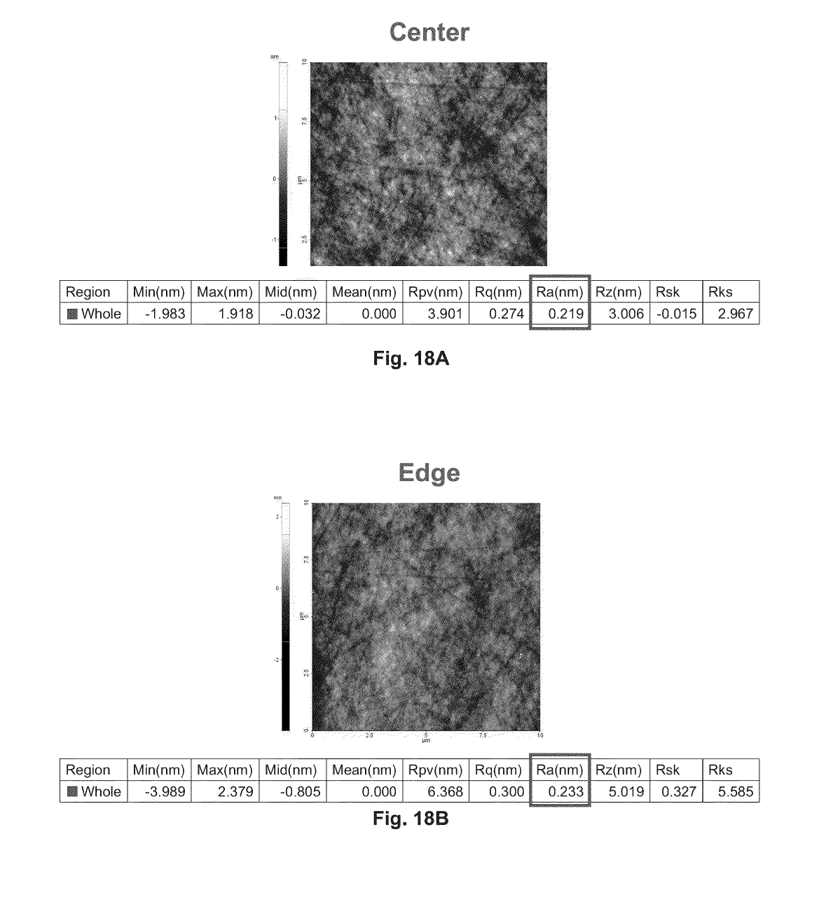

After removal of the residue, the wafers were inspected to determine if the sapphire surface had been compromised. FIG. 18 illustrates an AFM image of the wafer top surface indicating that substantially no etching of the sapphire wafer top surface had occurred after chemical treatment.

It was surprisingly discovered that the methods described herein were effective at removing essentially all of the residue, especially on the angled surface of the wafer, without substantially etching the wafer.

In the foregoing, reference to specific embodiments and the connections of certain components is illustrative. It will be appreciated that reference to components as being coupled or connected is intended to disclose either direct connection between said components or indirect connection through one or more intervening components as will be appreciated to carry out the methods as discussed herein. As such, the above-disclosed subject matter is to be considered illustrative, and not restrictive, and the appended claims are intended to cover all such modifications, enhancements, and other embodiments, which fall within the true scope of the present invention. Thus, to the maximum extent allowed by law, the scope of the present invention is to be determined by the broadest permissible interpretation of the following claims and their equivalents, and shall not be restricted or limited by the foregoing detailed description.

The Abstract of the Disclosure is provided to comply with Patent Law and is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all features of any of the disclosed embodiments. Thus, the following claims are incorporated into the Detailed Description, with each claim standing on its own as defining separately claimed subject matter.

What is claimed is:

1. A method for reclaiming a wafer comprising:
providing a wafer comprising sapphire and a residue deposited on the sapphire, wherein the residue comprises a III-V nitride;
immersing the wafer in a first etchant composition comprising KOH; and
polishing the wafer.

2. The method of claim 1, wherein the first etchant composition comprises a 10 to 90% KOH solution.

3. The method of claim 1, wherein the first etchant composition is heated to a temperature from 40 to 140° C.

4. The method of claim 1, wherein the wafer is immersed in the first etchant composition for a period of 8 to 40 hours.

5. The method of claim 1, further comprising imparting ultrasonic energy to the wafer during immersion of the wafer in the first composition.

6. The method of claim 1, further comprising polishing the wafer before immersing the wafer in the first composition.

7. A method for forming an electronic structure comprising:
providing a wafer comprising sapphire;
depositing a layer, wherein the depositing comprises an epitaxial deposition;
forming an electronic structure;
separating the layer and electronic structure from the wafer, wherein a residue remains on the wafer after separating, and wherein the residue comprises a III-V nitride;
immersing the wafer in a first etchant composition comprising KOH;
polishing the wafer; and
depositing another layer on the wafer, wherein the depositing comprises an epitaxial deposition.

8. The method of claim 2, wherein the process is repeated more than 2 times with the same wafer.

9. The method of claim 2, wherein the electronic structure comprises a light emitting diode (LED).

10. The method of claim 2, wherein the residue further comprises a metallic material.

11. The method of claim 10, further comprising immersing the wafer in a second etchant composition comprising an etchant configured to etch the metallic material, wherein immersing in the second etchant composition is performed before immersing in the first etchant composition.

12. The method of claim 11, wherein the second etchant composition comprises concentrated hydrochloric acid, HNO₃, or combinations thereof.

13. The method of claim 2, wherein the separating includes laser lift-off.

14. The method of claim 2, wherein the first etchant composition comprises a 10 to 90% KOH solution.

15. The method of claim 2, wherein the first etchant composition is heated to a temperature from 40 to 140° C.

16. The method of claim 2, wherein the wafer is immersed in the first etchant composition for a period of 8 to 40 hours.

17. The method of claim 2 further comprising imparting ultrasonic energy to the wafer during immersion of the wafer in the first and/or second composition.

18. The method of claim 11 further comprising chemically cleaning the wafer after immersing the wafer in the second composition.

19. The method of claim 2 further comprising rinsing the wafer with a third composition and drying the wafer, wherein the third composition comprises deionized water (DI).

20. A batch of at least 10 reclaimed wafers, wherein the batch of reclaimed wafers has an average content of residue on a surface of the wafer which covers from about 0.00001% to about 0.01% of the surface area of the surface of the wafer.
